(19) United States
(12) Patent Application Publication
(10) Pub. No.: US 2026/0047475 A1
(43) Pub. Date: Feb. 12, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Taejun Kim, Suwon-si (KR); Junwoo Park, Suwon-si (KR); Seunghwan Kim, Suwon-si (KR); Youngmin Lee, Suwon-si (KR); Yongkwan Lee, Suwon-si (KR); Wonhee Lee, Suwon-si (KR)

(21) Appl. No.: 19/025,441

(22) Filed: Jan. 16, 2025

(30) Foreign Application Priority Data
Aug. 7, 2024 (KR) 10-2024-0105750

(51) Int. Cl. H01L 23/31; H01L 23/373; H01L 23/42; H01L 23/498

(52) U.S. Cl. CPC H01L 23/3135; H01L 23/42; H01L 23/3736; H01L 23/49816

(57) ABSTRACT

An example semiconductor package includes a substrate, a semiconductor chip on the substrate, a heat-dissipation structure on the substrate, heat transfer paste, and a molding layer covering the heat transfer paste. The heat-dissipation structure is horizontally apart from the semiconductor chip. The heat transfer paste is between the semiconductor chip and the heat-dissipation structure. A top surface of the heat transfer paste is at a lower vertical level than a top surface of the heat-dissipation structure.

### CROSS-REFERENCE TO RELATED APPLICATION

This application claims priority under 35 U.S. C. § 119 to Korean Patent Application No. 10-2024-0105750, filed on Aug. 7, 2024, in the Korean Intellectual Property Office, the disclosure of which is incorporated by reference herein in its entirety.

### BACKGROUND

With the rapid development of the electronics industry and the demands of users, electronic devices become smaller and lighter. As the electronic devices become smaller and lighter, semiconductor packages used therein also become smaller and lighter and are also desired to have high reliability along with high performance and large capacity. As semiconductor packages become more highly efficient and larger in capacity, the power consumption of the semiconductor packages increases. Accordingly, the importance of improving the performance and heat dissipation characteristics of the semiconductor packages increases.

### SUMMARY

The present disclosure relates to a semiconductor package with improved heat dissipation characteristics and a method of manufacturing the same.

In general, according to some aspects, a semiconductor package includes a substrate, a semiconductor chip on the substrate, a heat-dissipation structure on the substrate, the heat-dissipation structure being horizontally apart from the semiconductor chip, heat transfer paste between the semiconductor chip and the heat-dissipation structure, and a molding layer covering the heat transfer paste, wherein a top surface of the heat transfer paste is at a lower vertical level than a top surface of the heat-dissipation structure.

In general, according to some aspects, a semiconductor package includes a substrate, a semiconductor chip on the substrate, a plurality of heat-dissipation structures on the substrate, the plurality of heat-dissipation structures being horizontally apart from the semiconductor chip, heat transfer paste between the semiconductor chip and the heat-dissipation structure, and a molding layer covering the heat transfer paste, wherein the plurality of heat-dissipation structures are arranged along at least one side of four sides of the semiconductor chip, and the heat-dissipation structures arranged along the at least one side of the four sides of the semiconductor chip are apart from each other in a direction in which the at least one side of the semiconductor chip extends.

In general, according to some aspects, a semiconductor package includes a substrate including a substrate base, a first upper pad and a second upper pad on a top surface of the substrate base, and a lower pad on a bottom surface of the substrate base, a semiconductor chip on the second upper pad of the substrate, a plurality of heat-dissipation structures on the first upper pad of the substrate, the plurality of heat-dissipation structures being horizontally apart from the semiconductor chip, heat transfer paste between the semiconductor chip and the heat-dissipation structure, and a molding layer covering the heat transfer paste, wherein a top surface of the heat transfer paste is at a lower vertical level than a top surface of the heat-dissipation structure, the plurality of heat-dissipation structures are arranged along each of four sides of the semiconductor chip, and the heat-dissipation structures arranged along each of the four sides of the semiconductor chip are apart from each other in a direction in which each of the four sides of the semiconductor chip extends.

### BRIEF DESCRIPTION OF THE DRAWINGS

Implementations will be more clearly understood from the following detailed description taken in conjunction with the accompanying drawings.

FIG. 1 is a plan layout diagram of some components of an example of a semiconductor package.

FIG. 2 is an example cross-sectional view taken along line A-A′ of FIG. 1.

FIG. 3 is a plan layout diagram of some components of an example of a semiconductor package.

FIG. 4 is an example cross-sectional view taken along line B-B′ of FIG. 3.

FIG. 5 is a cross-sectional view of an example of a semiconductor package.

FIGS. 6, 7, 8, 9, and 10 are cross-sectional views of an example of a method of manufacturing a semiconductor package.

### DETAILED DESCRIPTION

Hereinafter, implementations will be described in detail with reference to the accompanying drawings. The same reference numerals are used to denote the same elements in the drawings, and repeated descriptions thereof will be omitted.

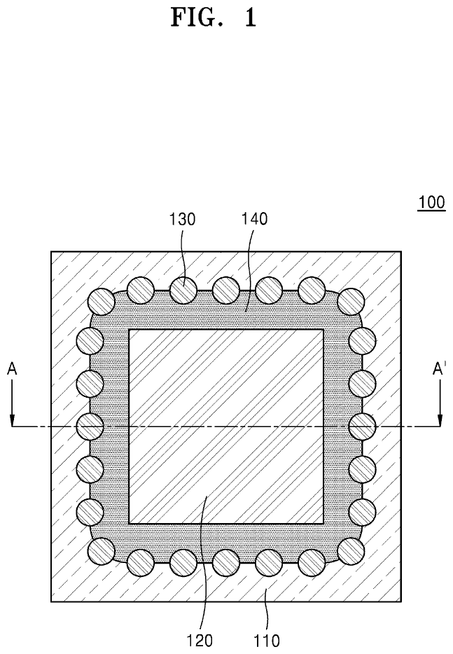

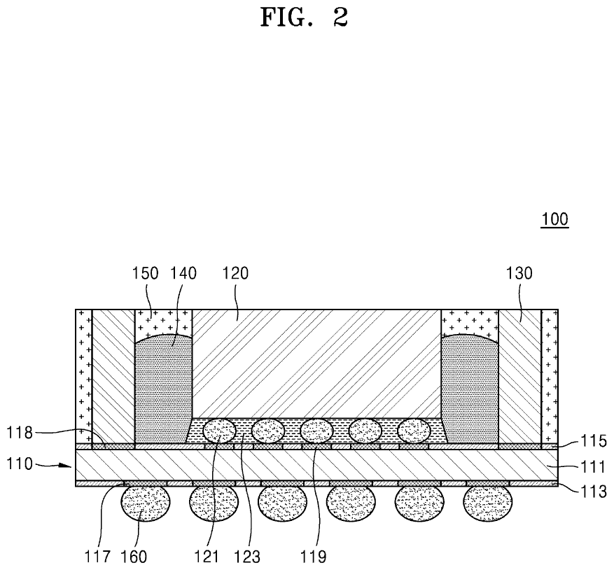

FIG. 1 is a plan layout diagram of some components of an example of a semiconductor package 100. FIG. 2 is an example cross-sectional view taken along line A-A′ of FIG. 1. For brevity, the illustration of a molding layer 150 is omitted among components of the semiconductor package 100 in FIG. 1.

Referring to FIGS. 1 and 2, the semiconductor package 100 may include a substrate 110, a semiconductor chip 120, a heat-dissipation structure 130, and heat transfer paste 140.

The substrate 110 may include a printed circuit board (PCB). For example, the substrate 110 may include a multi-layered PCB.

The substrate 110 may include a substrate base 111, a first upper pad 118 and a second upper pad 119, which are formed on a top surface of the substrate base 111, a lower pad 117 formed on a bottom surface of the substrate base 111, an upper insulating layer 115, and a lower insulating layer 113.

The substrate base 111 may include a single base layer or a structure in which a plurality of base layers are stacked. The substrate base 111 may include, for example, at least one material selected from a phenol resin, an epoxy resin, and polyimide. The substrate base 111 may include, for example, at least one material selected from Frame Retardant 4 (FR4), tetrafunctional epoxy, polyphenylene ether, epoxy/polyphenylene oxide, bismaleimide triazine (BT), Thermount, cyanate ester, polyimide, and a liquid crystal polymer.

A plurality of first upper pads 118 and a plurality of second upper pads 119 may be located on the top surface of the substrate base 111. Each of the plurality of first upper pads 118 may refer to an upper pad on an edge region of the substrate 110, and each of the plurality of second upper pads 119 may refer to an upper pad on a central region of the substrate 110. The heat-dissipation structure 130 to be described below may be located on each of the plurality of first upper pads 118, and a first connection terminal 121 to be described below may be located on each of the plurality of second upper pads 119.

The upper insulating layer 115 may be located on the top surface of the substrate base 111 to cover a sidewall of each of the plurality of first upper pads 118 and the plurality of second upper pads 119. The upper insulating layer 115 may cover the sidewall of each of the plurality of first upper pads 118 and the plurality of second upper pads 119 and expose a top surface of each of the plurality of first upper pads 118 and the plurality of second upper pads 119.

A plurality of lower pads 117 may be located on the bottom surface of the substrate base 111. An external connection terminal 160 to be described below may be located on each of the plurality of lower pads 117.

The lower insulating layer 113 covering a sidewall of each of the plurality of lower pads 117 may be located on the bottom surface of the substrate base 111. The lower insulating layer 113 may expose a bottom surface of each of the plurality of lower pads 117, while covering the sidewall of each of the plurality of lower pads 117.

The semiconductor chip 120 may be mounted on the substrate 110. The semiconductor chip 120 may include, for example, a processor unit. For instance, the semiconductor chip 120 may include a microprocessor unit (MPU), a graphics processor unit (GPU), a central processing unit (CPU), or an application processor (AP). The semiconductor chip 120 may include, for example, a memory chip. For example, the semiconductor chip 120 may be a volatile memory semiconductor chip, such as dynamic random access memory (DRAM) or static RAM (SRAM), or a non-volatile memory semiconductor chip, such as phase-change RAM (PRAM), magnetoresistive RAM (MRAM), ferroelectric RAM (FeRAM), or resistive RAM (ReRAM).

The semiconductor chip 120 may include a semiconductor substrate and a chip pad. In some implementations, the semiconductor substrate may include silicon (Si). In addition, the semiconductor substrate may include a semiconductor element, such as germanium (Ge), or a compound semiconductor, such as silicon carbide (SiC), gallium arsenide (GaAs), indium arsenide (InAs), and indium phosphide (InP).

The semiconductor substrate may include an active surface and an inactive surface facing the active surface. For example, the active surface may be a bottom surface of the semiconductor substrate, and the inactive surface may be a top surface of the semiconductor substrate, which faces the bottom surface of the semiconductor substrate.

The active surface of the semiconductor substrate may include a plurality of individual devices of various types. For example, the plurality of individual devices may include various microelectronic devices, for example, complementary metal-insulator-semiconductor (CMOS) transistors, metal-oxide-semiconductor field effect transistors (MOSFETs), system large-scale integration (LSI), image sensors (e.g., a CMOS imaging sensor (CIS)), a micro-electro-mechanical system (MEMS), active devices, and passive devices.

The chip pad may be located on the bottom surface of the semiconductor substrate, that is, an active surface of the semiconductor substrate. The chip pad may be electrically connected to a plurality of individual devices of various types, which are included in the active surface of the semiconductor substrate.

A plurality of first connection terminals 121 may be between the substrate 110 and the semiconductor chip 120. Each of the plurality of first connection terminals 121 may be in contact with a second upper pad 119 of the substrate 110 and a chip pad of the semiconductor chip 120. Each of the plurality of first connection terminals 121 may electrically connect the substrate 110 to the semiconductor chip 120. In some implementations, each of the plurality of first connection terminals 121 may include tin (Sn), silver (Ag), copper (Cu), nickel (Ni), or a combination thereof. In some implementations, each of the plurality of first connection terminals 121 may include a solder ball. An underfill layer 123 may be between the substrate 110 and the semiconductor chip 120 and surround the plurality of first connection terminals 121. The underfill layer 123 may include, for example, an epoxy resin.

The heat-dissipation structure 130 may be located on an edge region of the substrate 110. For example, each of a plurality of heat-dissipation structures 130 may be on the first upper pad 118 located on the edge region of the substrate 110.

On the substrate 110, the plurality of heat-dissipation structures 130 may be arranged to be horizontally apart from the semiconductor chip 120 and surround the semiconductor chip 120. For example, the semiconductor chip 120 may be located on the central region of the substrate 110, and the plurality of heat-dissipation structures 130 may be located on the edge region of the substrate 110 and surround the semiconductor chip 120 along four sides of the semiconductor chip 120.

The plurality of heat-dissipation structures 130 arranged to surround the semiconductor chip 120 may be apart from each other. For example, on the edge region of the substrate 110, the plurality of heat-dissipation structures 130 may be arranged along the four sides of the semiconductor chip 120 in a view from above. The plurality of heat-dissipation structures 130 arranged along any one of the four sides of the semiconductor chip 120 may be apart from each other in a direction in which the any one of the four sides of the semiconductor chip 120 extends. For example, the plurality of heat-dissipation structures 130 arranged along any one side of the semiconductor chip 120 extending in any one direction (e.g., a first direction) may be apart from each other in the first direction.

Each of the plurality of heat-dissipation structures 130 may have a cylindrical shape, but the present disclosure is not limited thereto. For example, the plurality of heat-dissipation structures 130 may each have a rectangular parallelepiped shape.

In some implementations, each of the plurality of heat-dissipation structures 130 may include copper (Cu), but the present disclosure is not limited thereto.

In some implementations, a top surface of each of the plurality of heat-dissipation structures 130 may be at the same vertical level as a top surface of the semiconductor chip 120.

Heat generated by an operation of the semiconductor chip 120 may be transferred to the heat-dissipation structure 130 through the heat transfer paste 140 described below. The heat transferred to the heat-dissipation structure 130 may be dissipated to the outside of the semiconductor package 100 through the heat-dissipation structure 130.

The heat transfer paste 140 may surround the semiconductor chip 120 on the substrate 110. The heat transfer paste 140 may cover a side surface of the underfill layer 123 and a portion of a side surface of the semiconductor chip 120. An inner portion of the heat transfer paste 140 may be in contact with the side surface of the underfill layer 123 and the portion of the side surface of the semiconductor chip 120. A part of an outer portion of the heat transfer paste 140 may be in contact with a portion of a sidewall of each of the plurality of heat-dissipation structures 130, and the remaining part of the outer portion of the heat transfer paste 140 may be covered by the molding layer 150. In some implementations, a top surface of the heat transfer paste 140 may be at a lower vertical level than the top surface of the heat-dissipation structure 130 and the top surface of the semiconductor chip 120. For example, the top surface of the heat transfer paste 140 may be at a lower vertical level than the top surface of the semiconductor chip 120 and be at a higher vertical level than a bottom surface of the semiconductor chip 120. In some implementations, the heat transfer paste 140 may include silver, but the present disclosure is not limited thereto. For example, the heat transfer paste 140 may include a highly thermally conductive metal, for example, copper (Cu), gold (Au), and nickel (Ni).

The molding layer 150 may cover the substrate 110 and the heat transfer paste 140 and cover a portion of the sidewall of the heat-dissipation structure 130 and a portion of a sidewall of the semiconductor chip 120. In some implementations, a top surface of the molding layer 150 may be at the same vertical level as the top surface of the heat-dissipation structure 130 and the top surface of the semiconductor chip 120. That is, the top surface of the semiconductor chip 120 and the top surface of the heat-dissipation structure 130 may be exposed and not covered by the molding layer 150. Because the top surface of the semiconductor chip 120 and the top surface of the heat-dissipation structure 130 are exposed, heat generated by an operation of the semiconductor chip 120 may be dissipated to the outside through the top surface of the semiconductor chip 120 and the top surface of the heat-dissipation structure 130.

In some implementations, the molding layer 150 may include an epoxy molding compound (EMC), but the present disclosure is not limited thereto.

A plurality of external connection terminals 160 may be located on the lower pad 117 of the substrate 110. Each of the plurality of external connection terminals 160 may be in contact with a selected one of the plurality of lower pads 117. The external connection terminal 160 may electrically connect the semiconductor package 100 to an external device. In some implementations, each of the plurality of external connection terminals 160 may include Sn, Ag, Cu, Ni, or a combination thereof. In some implementations, each of the plurality of external connection terminals 160 may include a solder ball or a bump.

The semiconductor package 100 may include the heat-dissipation structure 130 located on the edge region of the substrate 110 and the heat transfer paste 140 between the heat-dissipation structure 130 and the semiconductor chip 120 located on the central region of the substrate 110. Heat generated by an operation of the semiconductor chip 120 may be transferred to the heat-dissipation structure 130 through the heat transfer paste 140, and the heat transferred to the heat-dissipation structure 130 may be dissipated to the outside, and thus, the dissipation performance of the semiconductor package 100 may improve.

In addition, because the top surface of the semiconductor chip 120 and the top surface of the heat-dissipation structure 130 are exposed and not covered by the molding layer 150, the heat generated by the operation of the semiconductor chip 120 may be directly dissipated to the outside from the top surface of the semiconductor chip 120 and the top surface of the heat-dissipation structure 130. Thus, the dissipation performance of the semiconductor package 100 may improve.

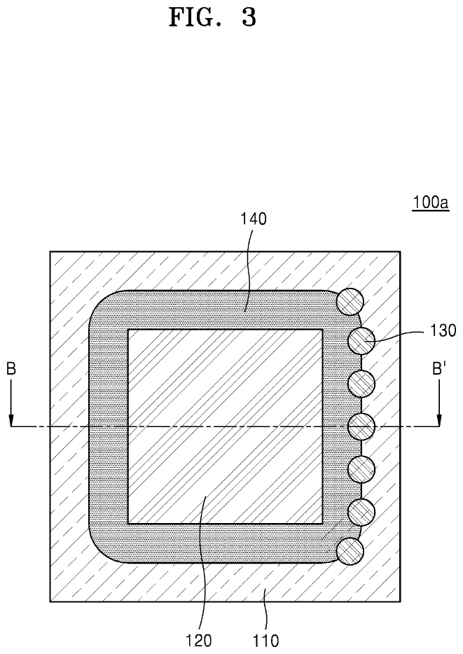

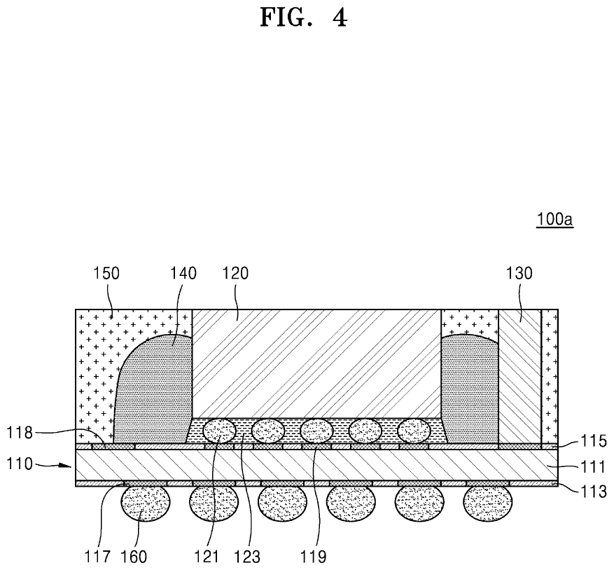

FIG. 3 is a plan layout diagram of some components of an example of a semiconductor package 100a. FIG. 4 is an example cross-sectional view taken along line B-B′ of FIG. 3. For brevity, the illustration of a molding layer 150 among components of the semiconductor package 100a is omitted in FIG. 3. Because respective components of the semiconductor package 100a shown in FIGS. 3 and 4 are similar to those of the semiconductor package 100 shown in FIGS. 1 and 2, the following description will focus on differences.

Referring to FIGS. 3 and 4, the semiconductor package 100a may substantially have a configuration similar to that of the semiconductor package 100 described with reference to FIGS. 1 and 2 except that a plurality of heat-dissipation structures 130 are arranged along any one of four sides of a semiconductor chip 120.

The semiconductor package 100a may include a substrate 110, a semiconductor chip 120, a heat-dissipation structure 130, and a heat transfer paste 140.

The heat-dissipation structure 130 may be located on an edge region of the substrate 110. For example, each of the plurality of heat-dissipation structures 130 may be on a first upper pad 118 located on the edge region of the substrate 110.

On the substrate 110, the plurality of heat-dissipation structures 130 may be arranged along any one of the four sides of the semiconductor chip 120. In addition, the plurality of heat-dissipation structures 130 arranged along the one side of the semiconductor chip 120 may be apart from each other in a direction in which the one side of the semiconductor chip 120 extends. That is, although the plurality of heat-dissipation structures 130 of the semiconductor package 100 shown in FIGS. 1 and 2 are arranged along each of the four sides of the semiconductor chip 120, the plurality of heat-dissipation structures 130 of the semiconductor package 100a shown in FIGS. 3 and 4 may be arranged along any one of the four sides of the semiconductor chip 120 and may not be arranged along the remaining three of the four sides of the semiconductor chip 120.

However, the present disclosure is not limited thereto. Unlike shown in FIGS. 3 and 4, the plurality of heat-dissipation structures 130 may be arranged along any two or three of the four sides of the semiconductor chip 120. In this case, the plurality of heat-dissipation structures 130 may be arranged along any two of the four sides of the semiconductor chip 120 and may not be arranged along the remaining two of the four sides of the semiconductor chip 120. Alternatively, the plurality of heat-dissipation structures 130 may be arranged along any three of the four sides of the semiconductor chip 120 and may not be arranged along the remaining one of the four sides of the semiconductor chip 120.

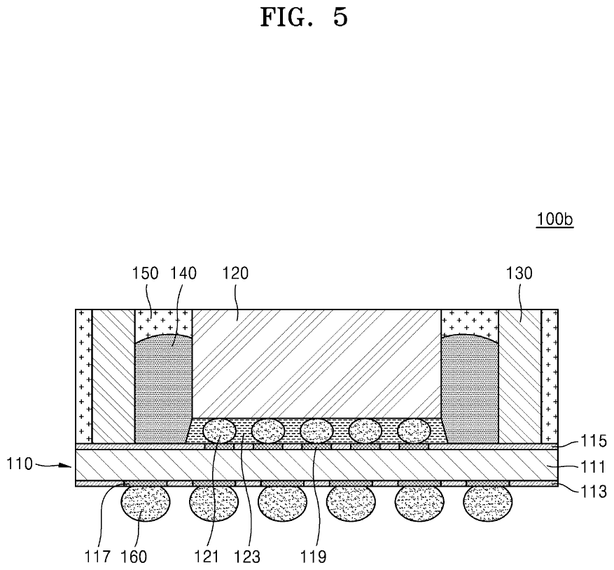

FIG. 5 is a cross-sectional view of an example of a semiconductor package 100b. Because respective components of the semiconductor package 100b shown in FIG. 1 are similar to those of the semiconductor package 100 shown in FIGS. 1 and 2, the following description will focus on differences.

Referring to FIG. 5, the semiconductor package 100b may substantially have a configuration similar to that of the semiconductor package 100 described with reference to FIGS. 1 and 2 except that a first upper pad 118 of a substrate 110 is omitted.

The semiconductor package 100b may include a substrate 110, a semiconductor chip 120, a heat-dissipation structure 130, and heat transfer paste 140.

The substrate 110 of the semiconductor package 100b may include a substrate base 111, a second upper pad 119 and a lower pad 117, which are respectively formed on a top surface and a bottom surface of the substrate base 111, an upper insulating layer 115, and a lower insulating layer 113. That is, although the substrate 110 of the semiconductor package 100 shown in FIGS. 1 and 2 includes the first upper pad 118 and the second upper pad 119, which are formed on the top surface of the substrate base 111, the substrate 110 of the semiconductor package 100b shown in FIG. 5 may not include the first upper pad (refer to 118 in FIG. 2). In this case, the heat-dissipation structure 130 may not be on the first upper pad (refer to 118 in FIG. 2) but on the upper insulating layer 115.

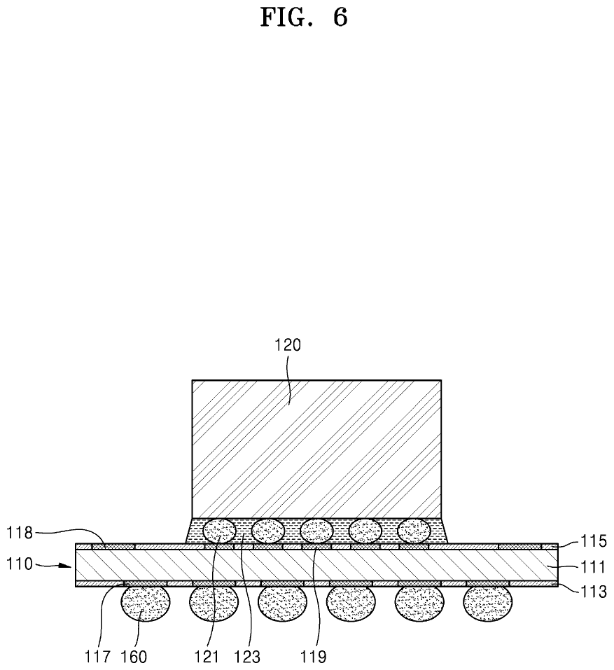

FIGS. 6, 7, 8, 9, and 10 are cross-sectional views illustrating an example of a method of manufacturing a semiconductor package 100.

Referring to FIG. 6, to begin with, a semiconductor chip 120 may be mounted on a substrate 110. To begin with, the semiconductor chip 120 may be arranged on the substrate 110 such that a first connection terminal 121 formed on a bottom surface of the semiconductor chip 120 overlaps a second upper pad 119 of the substrate 110 in a vertical direction. Thereafter, by using heat and pressure, the first connection terminal 121 may be connected to a chip pad of the semiconductor chip 120 and the second upper pad 119 of the substrate 110. Accordingly, the substrate 110 may be electrically connected to the semiconductor chip 120 through the first connection terminal 121. In some implementations, the semiconductor chip 120 may be mounted in a flip-chip form on the substrate 110.

Next, an underfill layer 123 may be formed to cover the first connection terminal 121. The underfill layer 123 may be formed by filling an underfill material layer (e.g., an epoxy resin) between the substrate 110 and the semiconductor chip 120.

Moreover, an external connection terminal 160 is illustrated as being formed on a lower pad 117 of the substrate 110 in FIG. 6, but the present disclosure is not limited thereto. For example, after processes described below are performed with reference to FIGS. 6 to 10, the external connection terminal 160 may be formed on the lower pad 117 of the substrate 110.

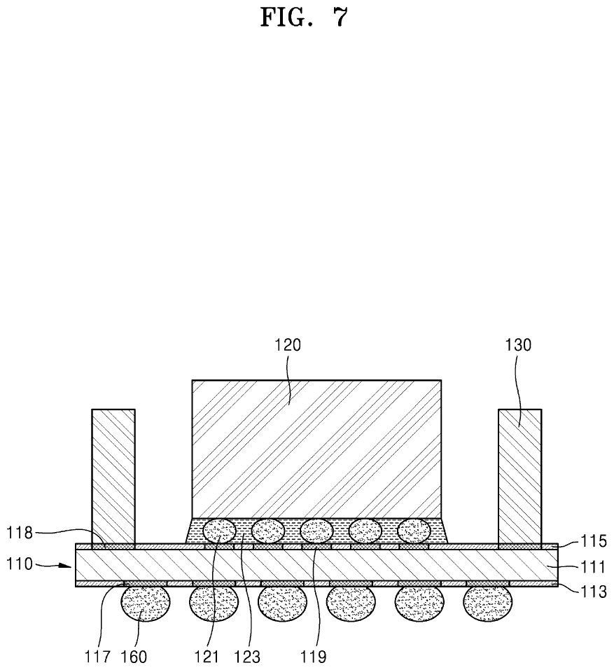

Referring to FIG. 7, in the resultant structure of FIG. 6, a heat-dissipation structure 130 may be formed on a first upper pad 118 of the substrate 110. The heat-dissipation structure 130 may be formed using, for example, a deposition process, but the present disclosure is not limited thereto.

In some implementations, the heat-dissipation structure 130 may be arranged along four sides of the semiconductor chip 120.

In some implementations, the heat-dissipation structure 130 may be arranged along only any one of the four sides of the semiconductor chip 120. In this case, the semiconductor package 100a shown in FIGS. 3 and 4 may be manufactured by performing processes described below with reference to FIGS. 3 and 4.

In some implementations, the heat-dissipation structure 130 may be arranged along any two of the four sides of the semiconductor chip 120 or along any three of the four sides of the semiconductor chip 120.

Next, a reflow process may be performed, and thus, the heat-dissipation structure 130 may be fixed to the first upper pad 118. A top surface of the semiconductor chip 120 may be at a higher vertical level than a top surface of the heat-dissipation structure 130.

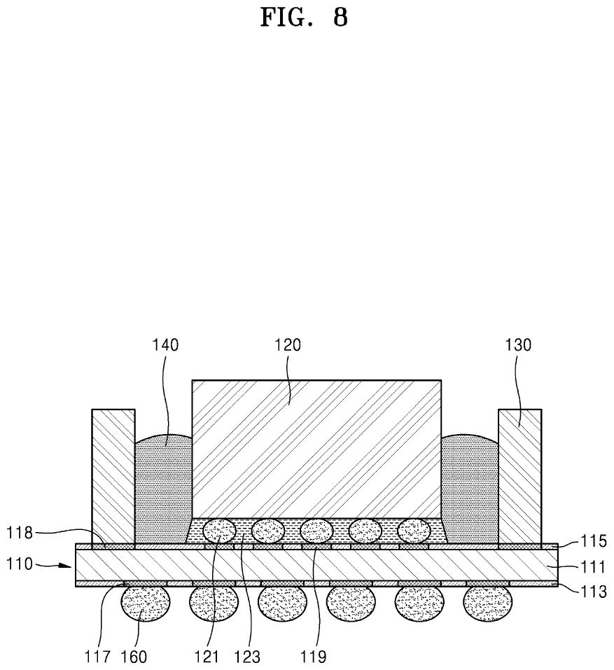

Referring to FIG. 8, in the resultant structure of FIG. 7, a thermally conductive material may be filled between a plurality of heat-dissipation structures 130 and the semiconductor chip 120 to form heat transfer paste 140. The thermally conductive material may include, for example, silver (Ag), but the present disclosure is not limited thereto. The heat transfer paste 140 may be in contact with a portion of a side surface of the semiconductor chip 120 and a portion of a side surface of each of the plurality of heat-dissipation structures 130. A top surface of the heat transfer paste 140 may be at a lower vertical level than the top surface of each of the plurality of heat-dissipation structures 130 and the top surface of the semiconductor chip 120. The heat transfer paste 140 may connect the plurality of heat-dissipation structures 130 to the semiconductor chip 120, and thus, a heat transfer path may be formed from the semiconductor chip 120 through the heat transfer paste 140 to the plurality of heat-dissipation structures 130.

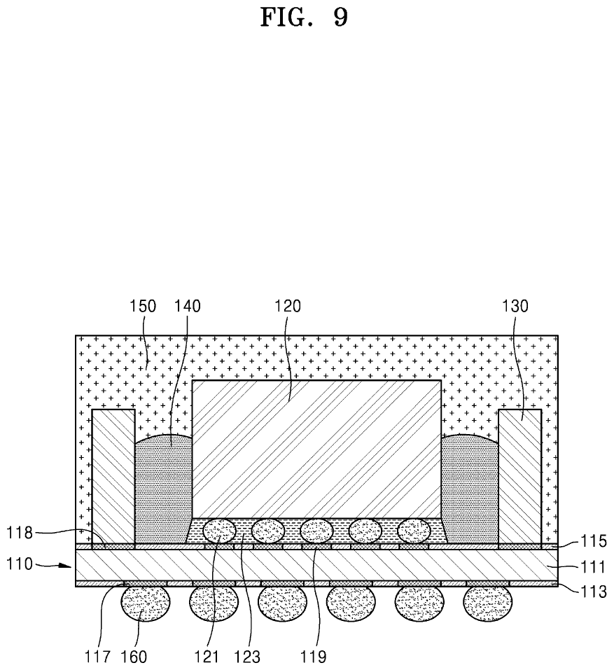

Referring to FIG. 9, in the resultant structure of FIG. 8, a molding layer 150 may be formed to cover the substrate 110, the plurality of heat-dissipation structures 130, and the heat transfer paste 140. In some implementations, the molding layer 150 may include an EMC, but the present disclosure is not limited thereto.

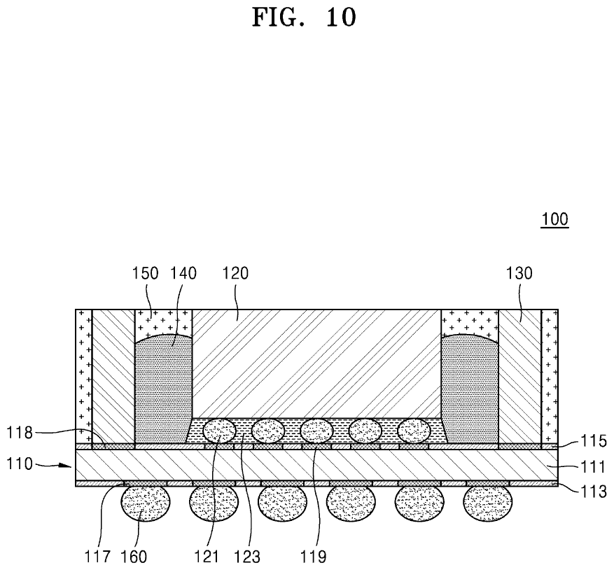

Referring to FIG. 10, in the resultant structure of FIG. 9, a planarization process may be performed to remove a portion of the molding layer 150 and a portion of the semiconductor chip 120. The planarization process may be, for example, a chemical mechanical polishing (CMP) process, but the present disclosure is not limited thereto. The portion of the molding layer 150 and the portion of the semiconductor chip 120 may be removed due to the planarization process, and thus, a top surface of the molding layer 150, a top surface of the semiconductor chip 120, and a top surface of the heat-dissipation structure 130 may be at the same vertical level. By completing the planarization process, the semiconductor package 100 may be manufactured.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A semiconductor package comprising:
a substrate;
a semiconductor chip on the substrate;
a heat-dissipation structure on the substrate, the heat-dissipation structure being horizontally spaced apart from the semiconductor chip;
heat transfer paste between the semiconductor chip and the heat-dissipation structure; and
a molding layer covering the heat transfer paste,
wherein a top surface of the heat transfer paste is at a lower vertical level than a top surface of the heat-dissipation structure.

2. The semiconductor package of claim 1, wherein the top surface of the heat transfer paste is at a lower vertical level than a top surface of the semiconductor chip, and the top surface of the heat transfer paste is at a higher vertical level than a bottom surface of the semiconductor chip.

3. The semiconductor package of claim 1, wherein a top surface of the molding layer, a top surface of the semiconductor chip, and the top surface of the heat-dissipation structure are at the same vertical level.

4. The semiconductor package of claim 1, wherein a plurality of heat-dissipation structures are positioned along at least one side of four sides of the semiconductor chip.

5. The semiconductor package of claim 4, wherein the plurality of heat-dissipation structures positioned along the at least one side of the four sides of the semiconductor chip are spaced apart from each other.

6. The semiconductor package of claim 1, wherein the substrate comprises a substrate base, an upper insulating layer on a top surface of the substrate base, and a first upper pad on the top surface of the substrate base, the upper insulating layer covering a plurality of side surfaces of the first upper pad and exposing a top surface of the first upper pad, and
wherein the heat-dissipation structure is on the first upper pad.

7. The semiconductor package of claim 1, wherein the substrate comprises a substrate base and an upper insulating layer, the upper insulating layer is on a top surface of the substrate base, and the heat-dissipation structure is on the upper insulating layer.

8. The semiconductor package of claim 1, wherein the heat-dissipation structure has a cylindrical shape.

9. A semiconductor package comprising:
a substrate;
a semiconductor chip on the substrate;
a plurality of heat-dissipation structures on the substrate, the plurality of heat-dissipation structures being horizontally spaced apart from the semiconductor chip; and
heat transfer paste between the semiconductor chip and the plurality of heat-dissipation structures; and
a molding layer covering the heat transfer paste,
wherein the plurality of heat-dissipation structures are positioned along at least one side of four sides of the semiconductor chip, and
wherein the plurality of heat-dissipation structures positioned along the at least one side of the four sides of the semiconductor chip are spaced apart from each other.

10. The semiconductor package of claim 9, wherein the plurality of heat-dissipation structures are positioned along each side of the four sides of the semiconductor chip and surround the semiconductor chip.

11. The semiconductor package of claim 9, wherein the plurality of heat-dissipation structures are positioned along a single side of the four sides of the semiconductor chip.

12. The semiconductor package of claim 9, wherein a top surface of the heat transfer paste is at a lower vertical level than a top surface of the plurality of heat-dissipation structures, and a top surface of the semiconductor chip and is at a higher vertical level than a bottom surface of the semiconductor chip.

13. The semiconductor package of claim 9, wherein a top surface of the molding layer, a top surface of the semiconductor chip, and a top surface of the plurality of heat-dissipation structures are at the same vertical level.

14. The semiconductor package of claim 9, wherein the substrate comprises a substrate base, an upper insulating layer on a top surface of the substrate base, and a first upper pad on a top surface of the substrate base, the upper insulating layer covering a plurality of side surfaces of the first upper pad and exposing a top surface of the first upper pad, and
wherein the plurality of heat-dissipation structures are on the first upper pad.

15. The semiconductor package of claim 9, wherein the substrate comprises a substrate base and an upper insulating layer, the upper insulating layer is on a top surface of the substrate base, and the plurality of heat-dissipation structures are on the upper insulating layer.

16. The semiconductor package of claim 9, wherein each heat-dissipation structure of the plurality of heat-dissipation structures has a cylindrical shape.

17. A semiconductor package comprising:
a substrate comprising a substrate base, a first upper pad, a second upper pad, and a lower pad, the first upper pad and the second upper pad being on a top surface of the substrate base, and the lower pad being on a bottom surface of the substrate base;
a semiconductor chip on the second upper pad of the substrate;
a plurality of heat-dissipation structures on the first upper pad of the substrate, the plurality of heat-dissipation structures being horizontally spaced apart from the semiconductor chip;
heat transfer paste between the semiconductor chip and the plurality of heat-dissipation structures; and
a molding layer covering the heat transfer paste,
wherein a top surface of the heat transfer paste is at a lower vertical level than a top surface of the plurality of heat-dissipation structures,
wherein the plurality of heat-dissipation structures are positioned along each side of four sides of the semiconductor chip, and
wherein the plurality of heat-dissipation structures positioned along each side of the four sides of the semiconductor chip are spaced apart from each other.

18. The semiconductor package of claim 17, wherein a top surface of the molding layer, a top surface of the semiconductor chip, and a top surface of the plurality of heat-dissipation structures are at the same vertical level.

19. The semiconductor package of claim 17, wherein the heat transfer paste comprises silver, and each heat-dissipation structure of the plurality of heat-dissipation structures comprises copper.

20. The semiconductor package of claim 17, wherein each heat-dissipation structure of the plurality of heat-dissipation structures has a cylindrical shape.
